(19) United States
(12) Patent Application Publication
(10) Pub. No.: US 2005/0104192 A1
(43) Pub. Date: May 19, 2005

(54) Electronic device

(76) Inventors: Shingo Masuko, Kawasaki (JP); Satoshi Ichikawa, Otawara (JP)

Correspondence Address: ARENT FOX PLLC, Suite 400, 1050 Connecticut Avenue, N.W., Washington, DC, 20036-5339, US

(21) Appl. No.: 10/967,338

(22) Filed: Oct. 19, 2004

(30) Foreign Application Priority Data
Oct. 23, 2003 (JP) 2003-363932

(51) Int. Cl. H01L 23/12

(52) U.S. Cl. 257/704; 257/732

(57) ABSTRACT

An electronic device having a cavity, which is included in a package, can be sealed with a lid surely and efficiently. A SAW device comprises a SAW chip that is fixed to a plane portion of a stem. A rear surface of the package is hermetically sealed with glass. An opening of a cavity provided on an upper surface of the package is hermetically sealed by a lid with seam welding. Glass is filled to reach the backside of flange of the stem. Such glass prevents the flange from being distorted by the weight of roller electrodes, and keeps the lid and the flange in contact with each other. In addition, the glass serves as a support, and prevents the current from leaking. Therefore, the lid and the flange are sufficiently and surely welded together.

### BACKGROUND OF THE INVENTION

1. Field of the Invention

This invention generally relates to an electronic device, and more particularly, to an electronic device having a surface acoustic wave device.

2. Description of the Related Art

In these years, electronic equipments have been small-sized with high-performance. With the advancements of the electronic devices, there has been a demand to downsize electronic chips that are included in the electronic devices and improve the performance thereof. Regarding a surface acoustic wave device (hereinafter referred to as SAW) employed for electronic devices, there has been a similar demand including a package thereof. The SAW device serves as a filter, a transversal filter, an oscillator, and the like, which are included in the electronic devices that send and receive electronic waves.

A conventional SAW device includes a SAW chip that is hermetically sealed in a cavity. The SAW chip includes a comb-like electrode named interdigital transducer (hereinafter simply referred to as IDT) arranged on a piezoelectric material substrate (hereinafter referred to as piezoelectric substrate). With the above-mentioned structure, an electric signal is applied to an input-side IDT, and is converted into a SAW so as to travel on the piezoelectric substrate. Then, an electric signal that has been modulated can be obtained from an output-side IDT.

FIG. 1 is a perspective view of a conventional SAW chip 110. Referring to FIG. 1, the SAW chip 110 comprises a metal pattern on one of main surfaces (referred to as a first main surface) of a piezoelectric substrate 111. The metal pattern includes one or more IDTs 113, electrode pads 114 for grounding, inputting and outputting signals, and an interconnection pattern 115 for electrically coupling the IDT 113 and the electrode pad 114.

The above-mentioned SAW chip 110 is hermetically sealed in a package having a cavity (as described in Japanese Patent Application Publication No.2001-60842). FIG. 2A is a partially cutaway perspective view of the SAW device 100. FIG. 2B is a cross-sectional view taken along a line C-C shown in FIG. 2A.

Referring to FIGS. 2A and 2B, the SAW device 100 includes a cavity 102 having an opening on one of the surfaces of a package (hereinafter referred to as upper surface). The SAW chip 110 is mounted inside the cavity 102 in a faceup state. An opposite surface to the first main surface of the SAW chip 110 (referred to as a second main surface) is fixed to the bottom of the cavity 102 with an adhesive 116.

The above-mentioned package includes a stem 101a, electrode pads 104, signal foot terminals 105a and ground foot terminals 105b. The stem 101a serves as a main structural frame of the package. The stem 101a forms a sidewall of the package and a plane portion 101c on which the SAW chip 110 is mounted. The SAW chip 110 is fixed to the plane portion 101c with the adhesive 116 in a faceup state.

An edge of the upper surface of the stem 101a is bent to form a flange 101b. The electrode pad 104 functions as an inner terminal provided in the cavity 102. The electrode pads 114 in the SAW chip 110 are electrically coupled to the electrode pads 104 with metal wires 107. That is, the SAW chip 110 and the package are joined by wire bonding. The electrode pads 104 are formed into a C-shape, and one end of each pad is exposed to a rear surface of the package. The electrode pads 104 exposed to the rear surface of the package serve as signal foot patterns 105a. That is, the electrode pads 114 of the SAW chip 110 are electrically extended to the rear surface of the package. Signals are applied to and output from the SAW chip 110 are via the signal foot patterns 105a. The ground foot patterns 105b, which are formed into a C-shape, are connected to the stem 101a. The ground foot patterns 105b function to prevent the package from being charged.

The rear surface of the package is hermetically sealed with a glass layer 106. The upper surface of the package is hermetically sealed with a lid 103. The package and the lid 103 are bonded by seam welding. The seam welding uses cylindrical roller electrodes 120, as shown in FIG. 2B. A jig 121 supports from below, the flange 101b of the stem 101a, on which the lid 103 is placed. The roller electrodes 120 rotate along the edge of the lid 103 from above. Here, electric current is flown via the roller electrodes 120. There exists contact resistance at a contact point between the lid 103 and the flange 101b, and heat is generated when the current that flows from one of the roller electrodes 120 passes through the contact point. Heat thus generated welds the lid 103 and the flange 101b.

However, in the case where the jig 121 supports the flange 101b as described above and the current flows from one of the roller electrodes 120 to the other, the current leaks through the jig 121. This leakage of current reduces the amount of heat and causes undesired welding between the flange 101b and the jig 121. A reduced amount of heat degrades welding efficiency. Moreover, there exists an unwelded area unexpectedly. Thus, productivity or yield ratio is decreased.

### SUMMARY OF THE INVENTION

The present invention has been made in view of the above circumstances and provides an electronic device having a package to which a lid can be sealed surely and efficiently.

According to an aspect of the present invention, an electronic device including a package having a cavity sealed with a lid, the package having a flange arranged around an opening of the cavity that faces upwards, and an insulating member provided on a downside of the flange. The opening has a shape of flange and an insulating material is employed for the rear surface of the flange, and the insulating material is able to support the flange when the lid is sealed with the flange. In the case where the lid is welded by seam welding, the insulating material is capable of preventing the flange from being distorted by the weight of the roller electrode or the like, and is also capable of keeping the lid and the flange in contact with each other. In addition, by supporting the flange with the insulating material, the insulating material is capable of preventing the current from leaking through the supporting material. Thus, the lid and flange can be welded surely and sufficiently.

### BRIEF DESCRIPTION OF THE DRAWINGS

Preferred embodiments of the present invention will be described in detail with reference to the following drawings, wherein:

FIG. 1 is a perspective view of a conventional SAW chip;

FIG. 2A is a partially cutaway perspective view of a SAW device;

FIG. 2B is a cross-sectional view taken along a line C-C shown in FIG. 2A;

FIG. 3A is a partially cutaway perspective view of a SAW device 10 according to a first embodiment of the present invention;

FIG. 3B is a cross-sectional view taken along a line A-A shown in FIG. 3A;

FIG. 4 illustrates a relation between an edge of a flange and an edge of a glass layer in accordance with the first embodiment of the present invention;

FIGS. 5A through 5D illustrate a manufacturing process in accordance with the first embodiment of the present invention; and

FIGS. 6A through 6C illustrate a manufacturing process following the process shown in FIGS. 5A through 5D.

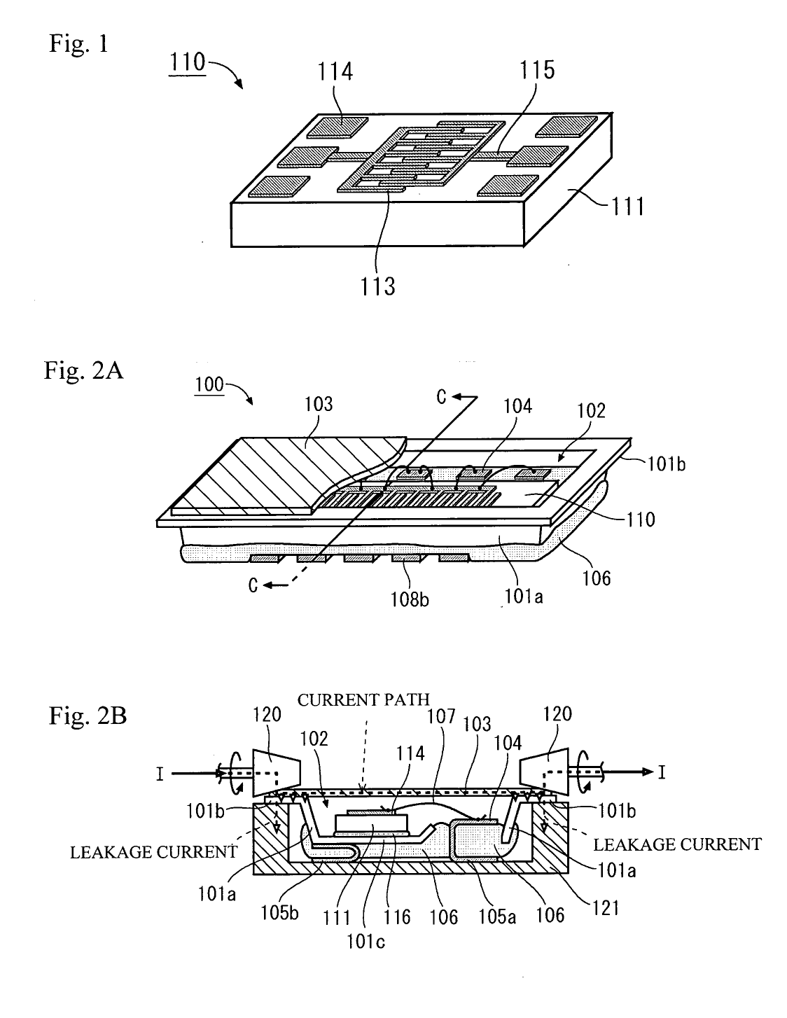

### DESCRIPTION OF THE PREFERRED EMBODIMENTS

A description will be given of a first embodiment of the present invention. The first embodiment is a SAW device equipped with a SAW chip housed in a package thereof. It is to be noted that the first embodiment includes electronic components having a cavity sealed with a sealing member such as a lid.

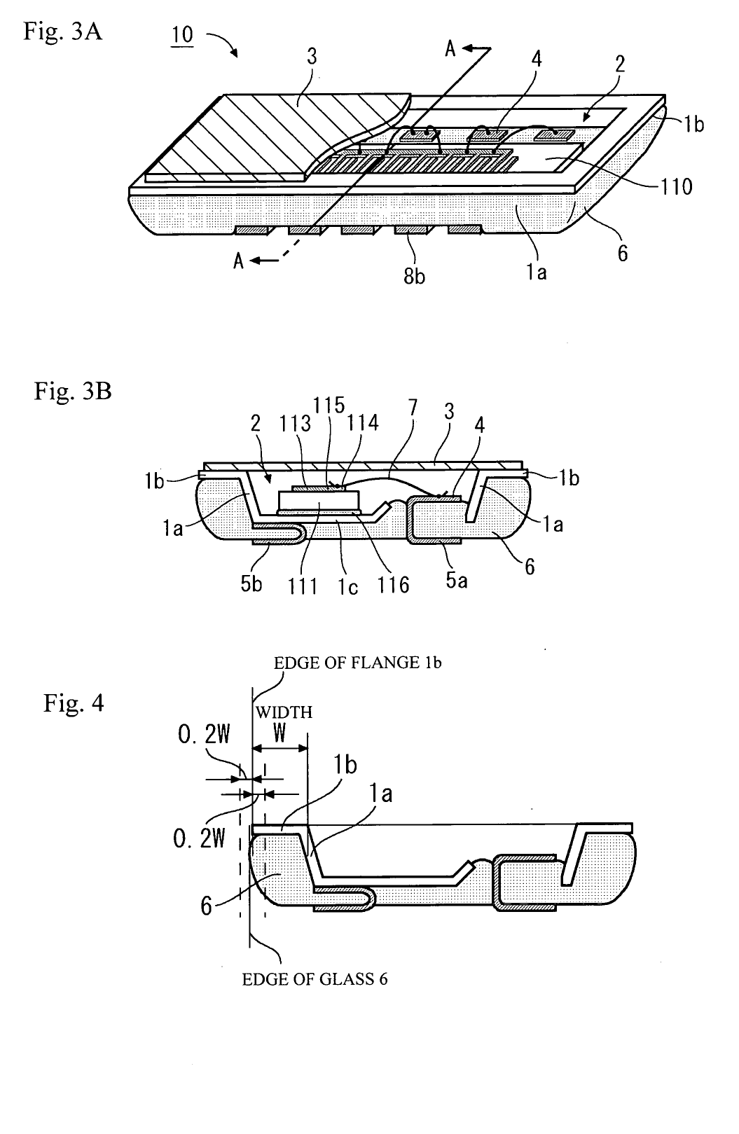

FIG. 3A shows a SAW device 10 in accordance with the first embodiment, and FIG. 3B is a cross-sectional view taken along a line A-A shown in FIG. 3A.

Referring to FIGS. 3A and 3B, the SAW device 10 includes a cavity 2 having an opening on one surface (upper surface) of a package. A SAW chip 110 is mounted in the cavity 2 in a faceup state. An upper surface of the SAW chip 110 is referred to as a first main surface. A second main surface, which is opposite to the first main surface, is fixed to the bottom of the cavity 2 with an adhesive 116 or the like. Here, the SAW chip denotes a chip on which SAW elements are arranged. In the faceup state, the backside of the SAW chip 110 is bonded to the package, while metal patterns such as IDTs, interconnection patterns and electrode pads face up.

The SAW chip 110 includes a piezoelectric substrate 111, which may be a lithium tantalate (LT) of rotated 42° Y-cut with X propagation. Hereinafter, the piezoelectric substrate 111 is referred to as LT substrate. Metal patterns are formed on the first main surface of the LT substrate 111. The metal patterns include an IDT 113, electrode pads 114, and interconnection patterns 115. A lithium niobate (LN) or quarts substrate may be substituted for the LT substrate 111. The metal patterns may be formed by a metal film that contains aluminum (Al). However, the metal patterns may be a metal film that contains copper (Cu), gold (Au), molybdic (Mo), tungsten (W), tantalum (Ta), chrome (Cr), titanium (Ti), platinum (Pt), ruthenium (Ru), rhodium (Rh) or the like. Also, the metal patterns may have a single layer or a multilayer structure. Laminated films that form the multilayer structure may be made of different materials.

Further, the package includes a stem la, electrode pads 4, signal foot patterns 5a, and ground foot patterns 5b. The stem 1a serves as a main structural frame of the package. The stem 1a defines a sidewall of the package and a plane portion 1c on which the SAW chip 110 is mounted. The stem 1a is made of a metal material, for example, alloy 42. The stem 1a may be made of any conductive material that has a mechanically and thermally sufficient strength. The metal material such as alloy 42 is used for forming the electrode pads 4, the signal foot patterns 5a, and the ground foot patterns 5b. Further, any metal material serving as an electrode may be employed.

An edge of the stem 1a on the upper side is bent to form a flange 1b around the cavity 2. The flange 1b has a width of, for example, 300 μm. Here, the width of the flange 1b denotes a length from the junction with the stem 1a to the edge of the flange 1b (see FIG. 4).

The SAW chip 110 is fixed to the plane portion 1c of the stem 1a with the adhesive 116 in the faceup state. The electrode pads 4 serve as inner terminals mounted in the cavity 2. The electrode pads 4 are electrically coupled to electrode pads 114 of the SAW chip 110 with metal wires 7. That is, the SAW chip 110 and the package are joined by wire bonding. The electrodes 4 are bent into a C-shape, and have ends exposed to the backside of the package. The electrode pads 4 exposed to the backside serve as the signal foot terminals 5a. In other words, the electrode pads 4 of the SAW chip 110 are electrically extended to the backside of the package. Signals are applied to and output from the SAW chip 110 via the signal foot terminals 5a. The ground foot terminals 5b, which are also bent a C-shape, are connected to the stem 1a. The ground foot patterns 5b are used to prevent the package from being charged and improve the filter characteristics.

The backside of the package is hermetically sealed with a glass layer 6, which is an insulating member. The glass layer 6 may include, for instance, borosilicate glass. Also the glass layer 6 may contain any of kalium (K), natrium (Na), or the like. Another insulating material may be used to form the layer. Preferably, a material having thermal softening characteristics is employed in terms of filling workability. Glass has a great advantage in inexpensiveness and thermal softening characteristics thereof.

The upper surface of the package is hermetically sealed with the lid 3. The package and the lid 3 are joined by standard seam welding. In accordance with the first embodiment of the present invention, the glass layer 6 is filled to reach the lower surface of the flange 1b in the stem 1a. This can prevent the flange 1b from being distorted by the weight of the roller electrodes 120 or the like, and can surely maintain the lid 3 in contact with the flange 1b, during the seam welding. The glass layer 6 serves as a support. Therefore, the glass layer 6 is able to prevent the current from leaking through the support (the glass layer 6), and is also able to weld the lid 3 and the flange 1b surely and efficiently.

The backside of the package is filled with the glass layer 6, which has an edge that is 25 μm further in than (set back from) the edge of the flange 1b. However, the present invention is not limited to the above arrangement, and may have variations, if the flange 1b can be supported from the backside with a sufficient strength. For example, referring to FIG. 4, the width of the flange 1b is set to W. In the case where the glass layer 6 is provided to −20 percent of the width W or more (minus denotes the inside from the edge of the flange 1b) from the edge of the flange 1b, the glass layer 6 is able to sufficiently support the flange 1b during the seam welding of the lid 3. In contrast, in the case where the glass layer 6 is filled to protrude from the edge of the flange 1b, as shown in FIG. 4, it is preferable that the glass layer 6 protrudes outwards from the edge of the flange 1b by +20 percent of the width W or less (plus denotes the outside from the edge of the flange 1b) in order to prevent the SAW device 10 from being larger.

A description will now be given of a manufacturing method of the SAW device 10 with the seam welding.

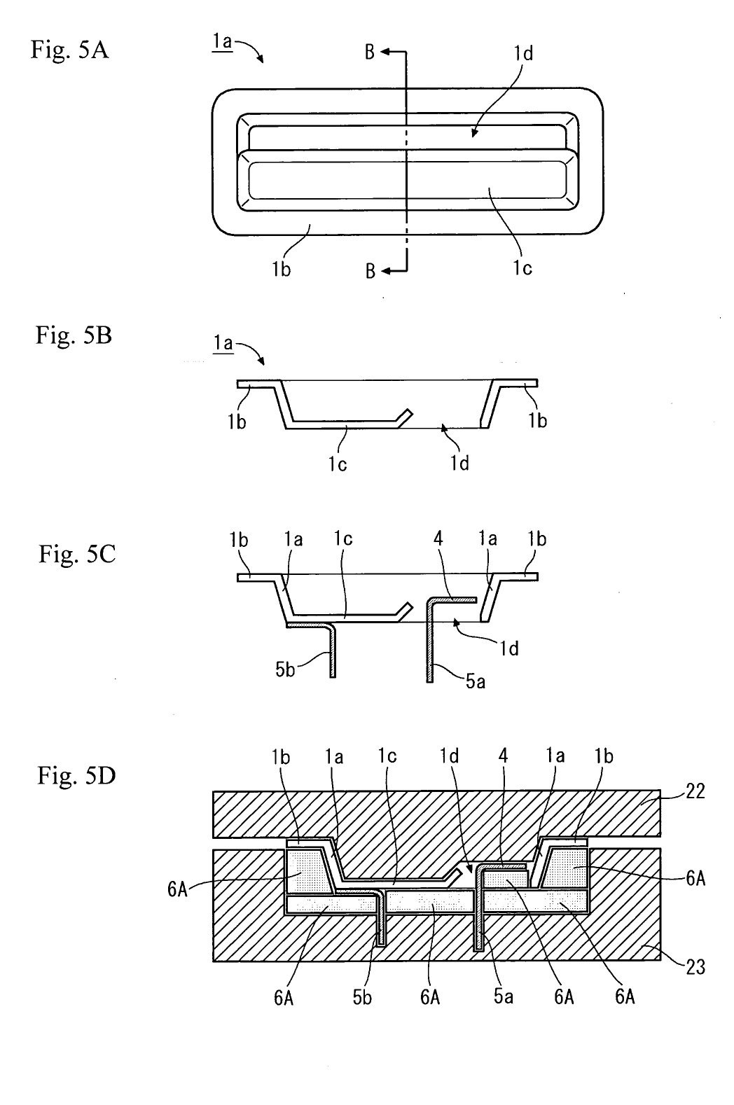

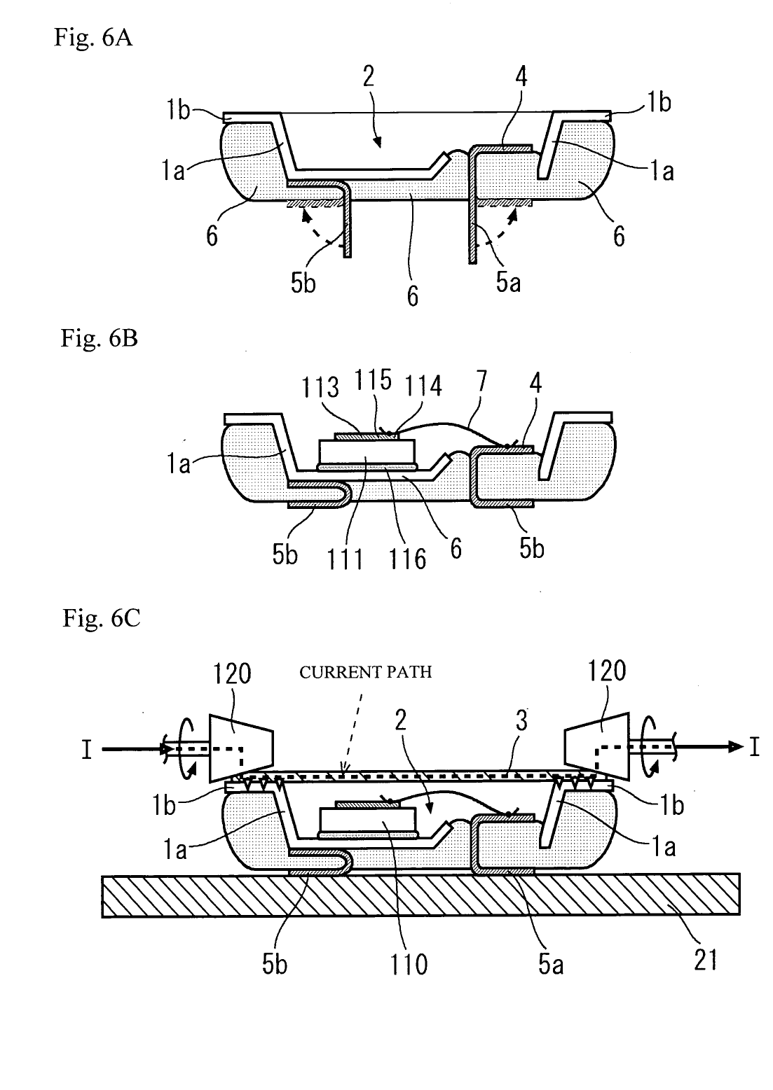

FIGS. 5A through 5D and FIGS. 6A through 6C show a method of manufacturing the SAW device 10. First, referring to FIGS. 5A and 5B, the stem 1a having the cavity 2 for mounting the SAW chip 110 is formed. FIG. 5A is a top view of the stem 1a. FIG. 5B is a cross-sectional view taken along a line B-B shown in FIG. 5A. The plane portion 1c is provided in the cavity 2 to mount the SAW chip 110. On the bottom of the stem 1a, an opening 1d is provided to locate metal members.

Referring to FIG. 5C, an L-shaped metal member is brought into contact with the backside of the plane portion 1c. Another L-shaped metal member is arranged in the opening 1d. The metal member provided on the backside of the plane portion 1c is to form the ground foot terminals 5b, and is to be bent into the C-shape in a later process. The metal member provided in the opening 1d is to form the electrode pad 4 and the signal foot terminals 5a, and is to be bent into the C-shape in a later process. In practice, multiple L-shaped metal members are provided to the backside of the plane portion 1c and multiple L-shaped metal members are provided inserted into the opening 1d.

After the metal materials are arranged as described above, referring to FIG. 5D, a block of glass is arranged (a glass block 6A), and is sandwiched by carbon jigs 22 and 23 from up and down. Then, the glass block 6A is melted by heating the carbon jigs 22 and 23, for instance, at approximately 900° C. The melted glass block 6A is adhered to the backside of the stem 1a leaving no space. The package is thus produced, and the backside of the stem 1a is hermetically sealed by the glass layer 6.

After the glass layer 6 is formed, referring to FIG. 6A, the metal members that protrude from the glass layer 6 are bent. Thus, the signal foot terminals 6a and the ground foot terminals 5b are formed.

Referring to FIG. 6B, the SAW chip 110 is fixed to the plane portion 1c of the stem 1a in the face-up state. Here, the plane portion 1c and the SAW chip 110 can be joined by, for example, a resin adhesive 116. The electrode pad 114 of the SAW chip 110 and the electrode pad 4 are bonded by a metal wire 7. Thus, the SAW chip 110 and the package are electrically coupled.

After the SAW chip 110 is mounted as described above, the package is located on a carrier sheet 21. While the SAW chip 110 is supported by the carrier sheet 21, the lid 3 is joined to the flange 1b by seam welding. This is performed by rotating two roller electrodes 120 along the outer edge of the lid 3 arranged on the flange 1b. The two roller electrodes 120 have a difference in potential so as to let the sufficient current flow and melt the lid 3. The roller electrodes 120 are brought into contact with the lid 3 arranged on the stem 1a, and a current path is formed from one roller electrode 120 to the other roller electrode 120 through the lid 3 and the flange 1b. There exists a contact resistance at a contact point between the lid 3 and the flange 1b and between the roller electrode 120 and the lid 3. Heat is generated when the current flows through the point at which the contact resistance exists. Thus, the current flowing between the two roller electrodes 120 melts the lid 3 that exists at the contact point, and the lid 3 and the flange 1b are bonded. Here, the backside of the flange 1b is supported by the glass layer 6. This can prevent the flange 1b from being distorted by the weight of the roller electrodes 120 or the like, and can surely support the lid 3 and the flange 1b in contact during the seam welding. Further, the support is made from glass that is an insulating material, and can prevent the current from leaking via the support (glass layer 6). Therefore, the lid 3 and the flange 1b can be surely and sufficiently welded together.

The description has been made of the SAW device 10 having the SAW chip 110 that is mounted in the package in the face-up state. However, the present invention is not limited to the above-mentioned embodiment, and the present invention may be applied to a SAW device having a SAW chip mounted in a package in a facedown state.

The present invention is not limited to the above-mentioned first embodiment, and other embodiments, variations and modifications may be made without departing from the scope of the present invention.

The present invention is based on Japanese Patent Application No. 2003-363932 filed on Oct. 23, 2003, the entire disclosure of which is hereby incorporated by reference.

1. An electronic device comprising:
a package having a cavity sealed with a lid, the package having a flange arranged around an opening of the cavity that faces upwards; and
an insulating member provided on a backside of the flange.

2. The electronic device as claimed as claim 1, wherein the insulating member is made of a thermal softening material.

3. The electronic device as claimed as claim 1, wherein the insulating member is made of glass.

4. The electronic device having a package as claimed as claim 1, wherein the insulating member has an edge that protrudes from or is set back from an edge of the flange in a range of minus 20 percent to plus 20 percent of a width of the flange.

5. The electronic device as claimed as claim 1, wherein the lid and the flange are welded together by seam welding.

6. The electronic device as claimed as claim 1, further comprising a surface acoustic wave device that includes a piezoelectric substrate having a surface on which metal patterns including comb-like electrodes are formed, wherein the surface acoustic wave device is provided in the cavity.
